(19) United States
(12) Patent Application Publication
(10) Pub. No.: US 2006/0113588 A1
(43) Pub. Date: Jun. 1, 2006

(54) Self-aligned trench-type DMOS transistor structure and its manufacturing methods

(75) Inventor: Ching-Yuan Wu, Hsinchu City (TW)

Correspondence Address: DENNISON, SCHULTZ, DOUGHERTY & MACDONALD, 1727 KING STREET, SUITE 105, ALEXANDRIA, VA, 22314, US

(73) Assignee: SILLICON-BASED TECHNOLOGY CORP.

(21) Appl. No.: 10/997,949

(22) Filed: Nov. 29, 2004

(51) Int. Cl. H01L 29/94

(52) U.S. Cl. 257/330

(57) ABSTRACT

The self-aligned trench-type DMOS transistor structure comprises a self-aligned source region being surrounded by a trench gate region. The self-aligned source region comprises a moderately-doped p-base diffusion region formed in a lightly-doped epitaxial semiconductor substrate, a self-aligned heavily-doped n⁺ source diffusion ring formed in a side surface portion of the moderately-doped p-base diffusion region, a heavily-doped p⁺ contact diffusion region formed in a surface portion of the moderately-doped p-base diffusion region surrounded by the heavily-doped n⁺ source diffusion ring, and a self-aligned source contact window formed by a semiconductor surface surrounded by a sidewall dielectric spacer. The trench gate region comprises a gate dielectric layer being lined over a trenched semiconductor surface with or without a thicker isolation dielectric layer formed on a bottom trenched semiconductor surface and a self-aligned highly conductive gate layer being formed at least over the gate dielectric layer.

### BACKGROUND OF THE INVENTION

1. Field of the Invention

The present invention relates generally to a trench-type DMOS power transistor and its manufacturing method and, more particularly, to a self-aligned trench-type DMOS transistor structure and its manufacturing methods.

2. Description of the Prior Art

A DMOS power transistor with very low on-resistance has become an important device for applications in battery protection, switching, linear regulator, amplifier and power management. Basically, the DMOS power transistor structure can be categorized into two groups: planar-type DMOS transistor structure and trench-type DMOS transistor structure. The planar-type DMOS transistor structure with MOS inversion channel being formed in a planar semiconductor surface, in general, exhibits a larger cell area and a larger turn-on resistance as compared to the trench-type DMOS transistor structure. Therefore, the trench-type DMOS transistor structure becomes a major trend for applications in fabricating DMOS power transistor and insulated-gate bipolar transistor (IGBT).

FIG. 1A shows a schematic cross-sectional view of a trench-type DMOS transistor structure of the prior art, in which a shallow trench is formed in a portion of an N⁻ epitaxial silicon layer 125 on an N⁺ silicon substrate 120 by using a masking photoresist step. The shallow trench being lined with a thermal oxide layer 112 and then filled with a doped polycrystalline-silicon layer 114 as a conductive gate layer is formed to isolate p-diffusion (or p-base) regions 105. A critical masking photoresist step (not shown) is performed to selectively form n⁺ source diffusion rings 130. Another critical masking photoresist step (not shown) is performed to pattern an oxide layer 140 over a shallow trench region and on a portion of nearby n⁺ source diffusion rings 130 and, thereafter, a self-aligned ion implantation is performed to form p⁺ contact diffusion regions 132 for forming p-base contacts.

Apparently, the doping concentration in the p⁺ contact diffusion regions 132 must be smaller than that in the n⁺ source diffusion rings 130. A metal layer 150 is formed over a surface portion of the n⁺ source diffusion rings 130 and the p⁺ contact diffusion regions 132 and is patterned to form a source electrode. It is clearly seen that two critical masking photoresist steps are required for forming the n⁺ source diffusion rings 130 and the p⁺ contact diffusion regions 132 and result in difficulty in scaling down the dimension of the p-diffusion regions 105. Moreover, the parasitic resistance of the doped polycrystalline-silicon layer 114 as a gate metal layer is very large for gate interconnection of many trench-type DMOS transistor cells and may result in a slower switching speed.

FIG. 1B shows a schematic cross-sectional view of another trench-type DMOS transistor structure of the prior art, in which a large p-diffusion region 204 is formed in an N⁻ epitaxial silicon layer 202 on an N⁺ silicon substrate 200 before forming the shallow trench; a gate-oxide layer 206g is lined over the shallow trench and a top portion of silicon surface; a doped polycrystalline-silicon layer 210 is formed to fill a portion of the shallow trench; and a thermal oxide layer 215 is then formed on a top portion of the doped polycrystalline-silicon layer 210. Similarly, a critical masking photoresist step (not shown) is performed to form n⁺ source diffusion rings 212 and another critical masking photoresist step (not shown) is performed to simultaneously pattern an oxide layer 214 and the gate-oxide layer 206g. There is no p⁺ diffusion region 132 as shown in FIG. 1A to improve contact resistance between the p-diffusion regions 204 and the source metal layer 216. It is clearly visualized that two critical masking photoresist steps are also required to form the n⁺ source diffusion rings 212 and the contacts for the source metal layer 216.

Comparing FIG. 1A and FIG. 1B, it is clearly seen that the overlapping region between the n⁺ source diffusion ring 212 and the doped polycrystalline-silicon layer 210 for FIG. 1B is reduced and this reduces the gate to source capacitance and improves leakage current between the n⁺ source diffusion rings 212 and the doped polycrystalline-silicon layer 210. Apparently, the trench-type DMOS transistor structure shown in FIG. 1B is also difficult to be scaled down due to two critical masking photoresist steps used to define the n⁺ source diffusion rings 212 and the source metal contacts.

It is therefore a major objective of the present invention to offer a self-aligned trench-type DMOS transistor structure being fabricated without critical masking photoresist steps.

It is another objective of the present invention to offer a self-aligned trench-type DMOS transistor structure with a heavily-doped source diffusion ring and a heavily-doped p-base contact diffusion region to improve device contact resistance and ruggedness.

It is a further objective of the present invention to offer a self-aligned trench-type DMOS transistor structure with different self-aligned conductive gate structures to reduce parasitic gate-interconnection resistance and capacitance.

It is yet an important objective of the present invention to offer a high-density, self-aligned trench-type DMOS transistor structure with a scalable p-base dimension.

### SUMMARY OF THE INVENTION

The present invention discloses a self-aligned trench-type DMOS transistor structure and its manufacturing methods. The self-aligned trench-type DMOS transistor structure of the present invention comprises a self-aligned source structure in a self-aligned source region and a self-aligned trench gate structure in a trench gate region, in which the self-aligned source structure comprises a moderately-doped p-base diffusion region, a self-aligned n⁺ source diffusion ring, a self-aligned p⁺ contact diffusion region, and a self-aligned source contact window; the self-aligned trench gate structure comprises a self-aligned heavily-doped polycrystalline-silicon gate layer, a self-aligned heavily-doped polycrystalline-silicon gate layer capped with a self-aligned conductive layer formed between a pair of capping sidewall dielectric spacers, or a self-aligned trenched heavily-doped polycrystalline-silicon gate layer being filled with an etched-back conductive layer formed between a pair of capping sidewall dielectric spacers. The self-aligned n⁺ source diffusion ring is formed in a side surface portion of the moderately-doped p-base diffusion region, wherein the moderately-doped p-base diffusion region is formed by a p-diffusion region divided by the trench gate region and the self-aligned n⁺ source diffusion ring is formed by a n⁺ diffusion region divided by the trench gate region. The p-diffusion region is formed in the lightly-doped N⁻ epitaxial silicon layer and the n⁺ diffusion region is formed in a surface portion of the p-diffusion region through a patterned window formed in the trench gate region. The self-aligned p⁺ contact diffusion region is formed by a self-aligned implantation window surrounded by a sidewall dielectric spacer formed over a sidewall of the trench gate region and on a side surface portion of a buffer oxide layer in the self-aligned source region. The self-aligned source contact window is formed in a self-aligned window surrounded by the sidewall dielectric spacer. The self-aligned trench-type DMOS transistor structure as described is fabricated by using only one masking photoresist step and exhibits the following advantages and features as compared to the prior arts: the self-aligned source region can be easily scaled down to have a minimum trench-type DMOS transistor size; the self-aligned n⁺ source diffusion ring and the self-aligned p⁺ contact diffusion region are heavily doped in a self-aligned manner to improve the source and p-base contact resistance and further to improve ruggedness of trench-type DMOS transistor; and a self-aligned highly conductive gate layer is used as a trench gate conductive layer to improve gate-interconnection parasitic resistance and a further scaling down of a trench width of the shallow trench can be easily obtained.

### BRIEF DESCRIPTION OF THE DRAWINGS

FIG. 1A and FIG. 1B show schematic cross-sectional views of prior-art trench-type DMOS transistor structures.

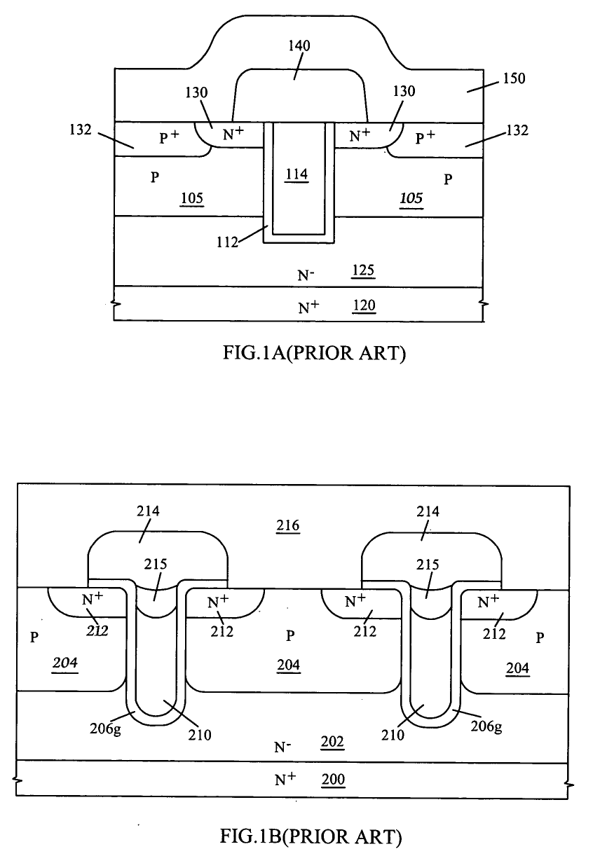

FIG. 2A through FIG. 2H show process steps and their schematic cross-sectional views of forming a first-type self-aligned trench-type DMOS transistor structure of the present invention.

FIG. 3A through FIG. 3B show simplified process steps after FIG. 2D and their schematic cross-sectional views of forming a second-type self-aligned trench-type DMOS transistor structure of the present invention.

FIG. 4A and FIG. 4B show simplified process steps after FIG. 2D and their schematic cross-sectional views of forming a third-type self-aligned trench-type DMOS transistor structure of the present invention.

FIG. 5A and FIG. 5B shows simplified process steps after FIG. 3A and their schematic cross-sectional views of forming a fourth-type self-aligned trench-type DMOS transistor structure of the present invention.

FIG. 6A and FIG. 6B show simplified process steps after FIG. 4A and their schematic cross-sectional views of forming a fifth-type self-aligned trench-type DMOS transistor structure of the present invention.

FIG. 7A and FIG. 7B show simplified process steps after FIG. 3A and their schematic cross-sectional views of forming a sixth-type self-aligned trench-type DMOS transistor structure of the present invention.

### DETAILED DESCRIPTION OF THE PREFERRED EMBODIMENTS

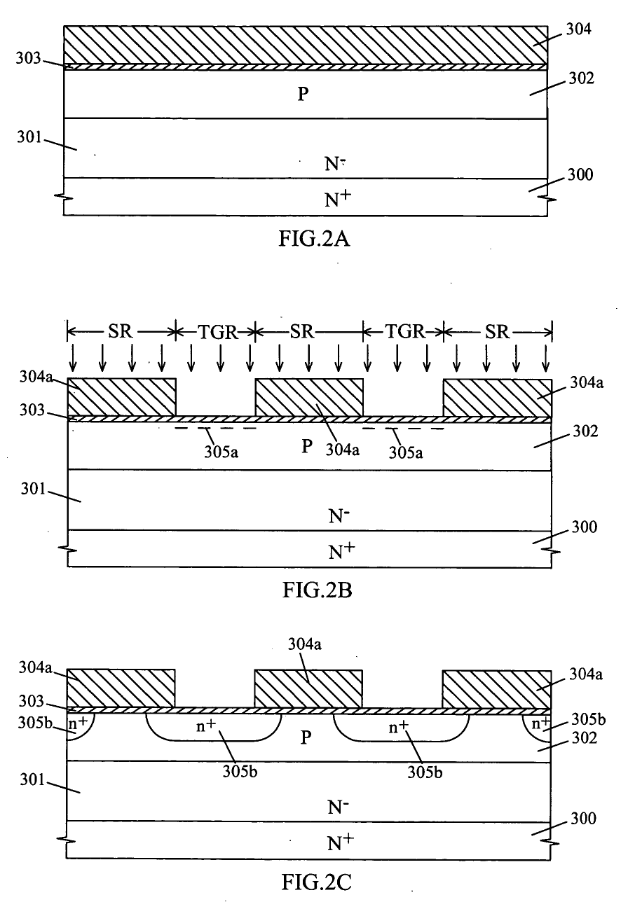

Referring now to FIG. 2A through FIG. 2H, there are shown process steps and their schematic cross-sectional views of fabricating a first-type self-aligned trench-type DMOS transistor structure of the present invention.

FIG. 2A shows that a lightly-doped N⁻ epitaxial silicon layer 301 is formed on a heavily-doped N⁺ silicon substrate 300; a p-diffusion region 302 is formed on the lightly-doped N⁻ epitaxial silicon layer 301; a buffer oxide layer 303 is formed on the p-diffusion region 302; and subsequently, a masking dielectric layer 304 is formed on the buffer oxide layer 303. The heavily-doped N⁺ silicon substrate 300 is preferably to have a resistivity between 0.001 *cm and 0.004 *cm and a thickness between 300 μm and 800 μm, depending on wafer size. The lightly-doped N⁻ epitaxial silicon layer 301 is preferably to have a resistivity between 0.1 *cm and 100 *cm and a thickness between 1 μm and 100 μm. The p-diffusion region 302 is formed by boron ion-implantation with a moderate dose between 10¹³/cm² and 5*10¹⁴/cm² and its junction depth is between 0.8 μm and 3 μm. The buffer oxide layer 303 is preferably a thermal silicon dioxide layer formed by using a conventional thermal oxidation process and its thickness is preferably between 200 Angstroms and 1000 Angstroms. The masking dielectric layer 304 is preferably made of silicon nitride as deposited by low-pressure chemical vapor deposition (LPCVD) and its thickness is preferably between 3000 Angstroms and 8000 Angstroms.

FIG. 2B shows that a first masking photoresist (PR1) step (not shown) is performed to define a plurality of self-aligned source regions (SR) with each of the plurality of self-aligned source regions (SR) surrounded by a trench gate region (TGR); the masking dielectric layer 304 in the trench gate region (TGR) is removed by using anisotropic dry etching and the patterned first masking photoresist (PR1) are then removed; and subsequently, ion-implantation is performed in a self-aligned manner by implanting a high dose of doping impurities across the buffer oxide layer 303 into a surface portion of the p-diffusion region 302 to form an implant region 305a. It should be noted that a rotated high angle-tilted implantation can be used to offer a larger lateral extension of a heavily-doped n⁺ diffusion region 305b.

FIG. 2C shows that a drive-in process is performed to form the heavily-doped n⁺ diffusion region 305b.

FIG. 2D shows that the buffer oxide layer 303 in the trench gate region (TGR) is removed by anisotropic dry etching; and subsequently, a shallow trench is formed in the lightly-doped N⁻ epitaxial silicon layer 301 with a trench depth slightly larger than a junction depth of the p-diffusion region 302. It is clearly seen that the p-diffusion region 302 is divided by the shallow trench (TGR) into a moderately-doped p-base diffusion region 302a in each of the plurality of self-aligned source regions (SR) and the heavily-doped n⁺ diffusion region 305b is divided by the shallow trench into a heavily-doped n⁺ source diffusion ring 305c in each of the plurality of self-aligned source regions (SR). It should be emphasized that a cleaning process (not shown) is performed to eliminate trench-induced defects over a trenched semiconductor surface. The cleaning process may include a thermal oxidation process for forming a liner oxide layer over the trenched semiconductor surface and the liner oxide layer is then removed by dipping in a dilute hydrofluoric acid or using buffered hydrofluoric acid.

FIG. 2E shows that a gate dielectric layer 306a is formed over an exposed silicon surface in the shallow trench and an etched-back polycrystalline-silicon layer 307a is formed to partially fill a gap in the trench gate region (TGR) and ion implantation is performed in a self-aligned manner to heavily dope the etched-back polycrystalline-silicon layer 307a by using arsenic or phosphorous doping impurities. The etched-back polycrystalline-silicon layer 307a is formed by first depositing a polycrystalline-silicon layer 307 (not shown) with a thickness approximately equal to or larger than one half width of the trench gate region (TGR) and then etching back the deposited polycrystalline-silicon layer 307 to a depth slightly larger than a top surface level of the patterned buffered oxide layer 303a. It should be noted that the etched-back polycrystalline-silicon layer 307a can be formed by planarizing the deposited polycrystalline-silicon layer 307 using chemical-mechanical polishing (CMP) and then etching back to a desired depth.

FIG. 2F shows that a thermal oxidation process is performed to form a planarized capping oxide layer 308a on a self-aligned heavily-doped polycrystalline-silicon gate layer 307b and to simultaneously activate and redistribute the implanted doping impurities. The thermal oxidation process can be performed in a dry oxygen ambient or in a steam or wet oxygen ambient. It should be noted that a top surface level of the planarized capping oxide layer 308a can be higher than that of the patterned masking dielectric layer 304a.

FIG. 2G shows that the patterned masking dielectric layer 304a in each of the plurality of self-aligned source regions (SR) is removed by using hot-phosphoric acid or anisotropic dry etching; a sidewall dielectric spacer 309a is then formed over a sidewall of the planarized capping oxide layer 308a and on a side surface portion of the patterned buffer oxide layer 303a in each of the plurality of self-aligned source regions(SR); and subsequently, ion implantation is performed in a self-aligned manner to form a heavily-doped p⁺ contact diffusion region 310a in a surface portion of the moderately-doped p-base diffusion region 302a surrounded by the heavily-doped n⁺ source diffusion ring 305c. It should be noted that a boron dose of the ion-implantation for forming the heavily-doped p⁺ contact diffusion region 310a should be smaller than that for forming the heavily-doped n⁺ source diffusion ring 305c and the ion-implantation can be separated into two stages i.e., a low-energy implantation for forming a shallow implant region and a high-energy implantation for forming a deeper implant region.

FIG. 2H shows that the patterned buffer oxide layer 303a surrounded by the sidewall dielectric spacer 309a in each of the plurality of self-aligned source regions (SR) is removed by anisotropic dry etching or wet etching to form a self-aligned source contact window in each of the plurality of self-aligned source regions (SR); a well-known self-aligned silicidation process is performed to form a self-aligned metal-silicide layer 311a over the self-aligned source contact window in each of the plurality of self-aligned source regions (SR); and subsequently, a source metal layer 312 is formed over the self-aligned metal-silicide layer 311a and the sidewall dielectric spacer 309a in each of the plurality of self-aligned source regions (SR) and the planarized capping oxide layer 308a in the trench gate region (TGR).

It is clearly seen that the first-type self-aligned trench DMOS transistor structure of the present invention is fabricated without using critical masking photoresist step and less masking photoresist steps are required as compared to the prior art.

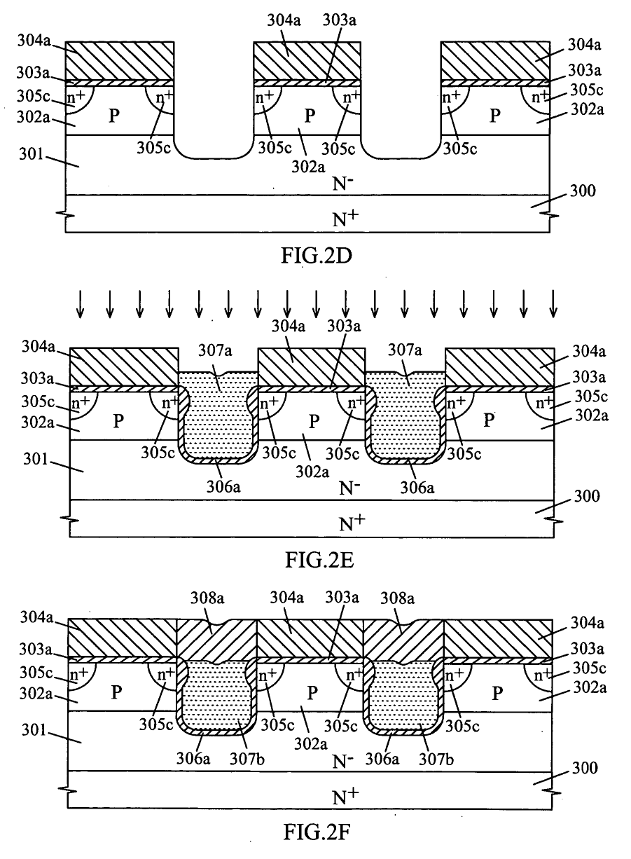

Referring now to FIG. 3A and FIG. 3B, there are shown simplified process steps after FIG. 2D and their schematic cross-sectional views of fabricating a second-type self-aligned trench DMOS transistor structure of the present invention.

FIG. 3A shows that a thicker isolation dielectric layer 313a is formed over a bottom trenched semiconductor surface of the shallow trench. The thicker isolation dielectric layer 313a is preferably made of silicon dioxide as deposited by LPCVD and is formed by first depositing a silicon dioxide layer 313 (not shown) with a thickness approximately equal to or larger than one half width of the trench gate region (TGR) to fill a gap in the trench gate region (TGR) and then etching back the deposited silicon dioxide layer 313 to a level slightly lower than a bottom junction depth of the moderately-doped p-base diffusion region 302a.

Following the same process steps shown in FIG. 2E through FIG. 2H, FIG. 3B can be easily obtained. It is clearly seen that the thicker isolation dielectric layer 313a shown in FIG. 3B may largely reduce gate to drain capacitance and increases breakdown voltage between gate to drain electrodes, as compared to FIG. 2H.

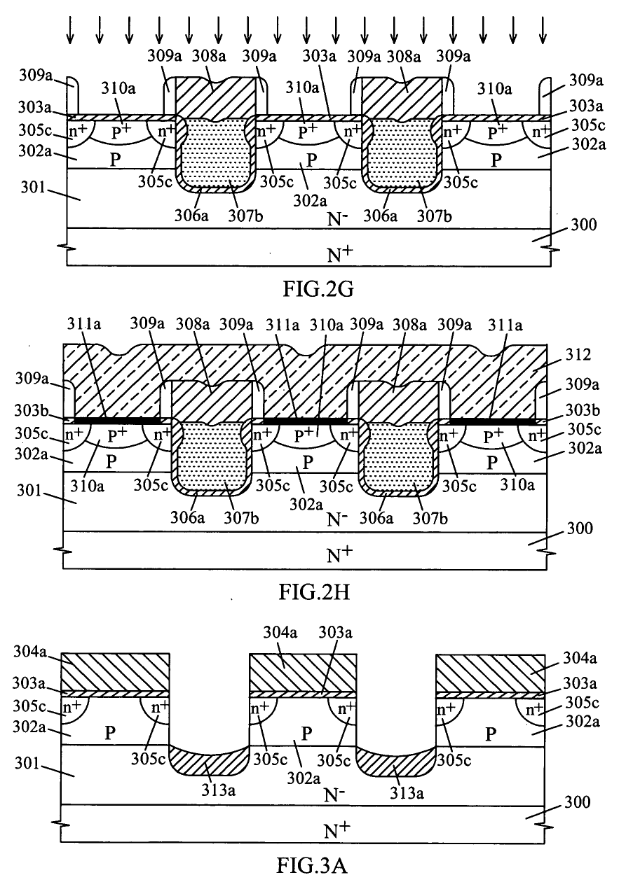

Referring now to FIG. 4A and FIG. 4B, there are shown simplified process steps after FIG. 2D and their schematic cross-sectional views of fabricating a third-type self-aligned trench-type DMOS transistor structure of the present invention.

FIG. 4A shows that a self-aligned heavily-doped polycrystalline-silicon gate layer 307b is formed over a portion of the gate dielectric layer 306a; and a pair of capping sidewall dielectric spacers 314a are then formed over sidewalls of the patterned masking dielectric layers 304a and on side surface portions of the self-aligned heavily-doped polycrystalline-silicon gate layer 307b. The pair of capping sidewall dielectric spacers 314a are preferably made of silicon dioxide as deposited by LPCVD and is formed by first depositing a silicon dioxide layer 314 (not shown) over a formed structure surface and then etching back a thickness of the deposited silicon dioxide layer 314. It should be noted that a high-dose ion implantation can be performed before or after forming the pair of capping sidewall dielectric spacers 314a to heavily dope the self-aligned heavily-doped polycrystalline-silicon gate layer 307b and the implanted doping impurities are preferably arsenic or phosphorous. It is clearly seen that the pair of capping sidewall dielectric spacers 314a are used to eliminate leakage current and reduce overlapping capacitance between the heavily-doped n⁺ source diffusion ring 305c and the self-aligned heavily-doped polycrystalline-silicon gate layer 307b.

FIG. 4B shows that a self-aligned highly conductive layer 315a is formed on the self-aligned heavily-doped polycrystalline-silicon gate layer 307b between the pair of capping sidewall dielectric spacers 314a; and subsequently, a planarized capping oxide layer 316a is formed over the self-aligned highly conductive layer 315a. The self-aligned highly conductive layer 315a comprises a self-aligned metal silicide layer being formed by a self-aligned silicidation process or an etched-back conductive layer being formed to partially fill a gap between the pair of capping sidewall dielectric spacers 314a. The planarized capping oxide layer 316a is preferably made of silicon dioxide as deposited by LPCVD and is formed by first depositing a silicon dioxide layer 316 (not shown) to fill a gap between the pair of capping sidewall dielectric spacers 314a and then etching back a thickness of the deposited silicon dioxide layer 316. Following the same process steps shown in FIG. 2G and FIG. 2H, FIG. 4B can be easily obtained. From FIG. 4B, it is clearly seen that the self-aligned highly conductive layer 315a may largely improve the gate-interconnection parasitic resistance, as compared to FIG. 2H. Moreover, the pair of capping sidewall dielectric spacers 314a may reduce leakage current paths and source to gate capacitance between the heavily-doped n⁺ source diffusion ring 305c and the self-aligned heavily-doped polycrystalline-silicon gate layer 307b.

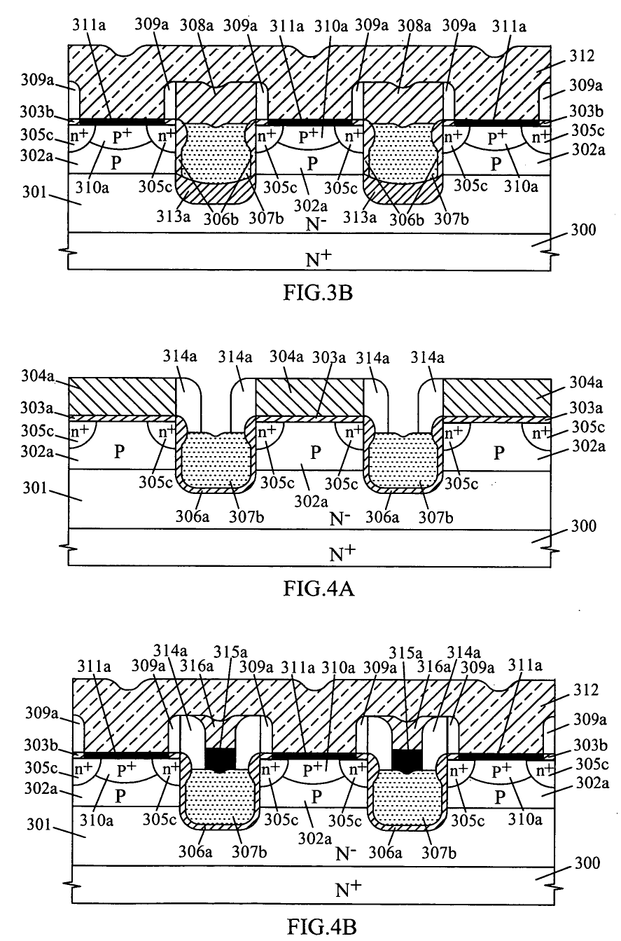

Referring now to FIG. 5A and FIG. 5B, there are shown simplified process steps after FIG. 3A and their schematic cross-sectional views of fabricating a fourth-type self-aligned trench-type DMOS transistor structure of the present invention.

FIG. 5A shows that a gate dielectric layer 306b is formed over an exposed silicon surface in the shallow trench and a self-aligned heavily-doped polycrystalline-silicon gate layer 307b is formed over the gate dielectric layer 306b and on the thicker isolation dielectric layer 313a; a pair of capping sidewall dielectric spacers 314a are then formed over sidewalls of the patterned masking dielectric layers 304a and on side surface portions of the self-aligned heavily-doped polycrystalline-silicon gate layer 307b; a self-aligned highly conductive layer 315a is formed on the self-aligned heavily-doped polycrystalline-silicon gate layer 307b between the pair of capping sidewall dielectric spacers 314a; and subsequently, a planarized capping oxide layer 316a is formed over the self-aligned highly conductive layer 315a. The self-aligned highly conductive layer 315a comprises a self-aligned metal silicide layer being formed by using a well-known self-aligned silicidation process or an etched-back conductive layer being formed to partially fill a gap between the pair of capping sidewall dielectric spacers 314a. The planarized capping oxide layer 316a is preferably made of silicon dioxide as deposited by LPCVD and is formed by first depositing a silicon dioxide layer 316 (not shown) to fill a gap between the pair of capping sidewall dielectric spacers 314a and then etching back a thickness of the deposited silicon dioxide layer 316. The self-aligned metal silicide layer is preferably made of titanium disilicide (TiSi₂), cobalt disilicide (CoSi₂) or nickle disilicide (NiSi₂). The etched-back conductive layer is preferably made of tungsten disilicide (WSi₂) or tungsten (W) as deposited by LPCVD and is formed by first depositing a tungsten disilicide (WSi₂) or tungsten (W) layer over a formed structure surface and then etching back a thickness of the deposited tungsten disilicide or tungsten layer.

Following the same process steps shown in FIG. 2H and FIG. 2G, FIG. 5B can be easily obtained. Apparently, FIG. 5B offers the self-aligned highly conductive layer 315a to reduce the gate-interconnection parasitic resistance, as compared to FIG. 3B. Moreover, FIG. 5B offers a pair of capping sidewall dielectric spacers 314a to reduce leakage current paths and source to gate capacitance between the heavily-doped n⁺ source diffusion ring 305c and the self-aligned heavily-doped polycrystalline-silicon gate layer 307b, as compared to FIG. 3B.

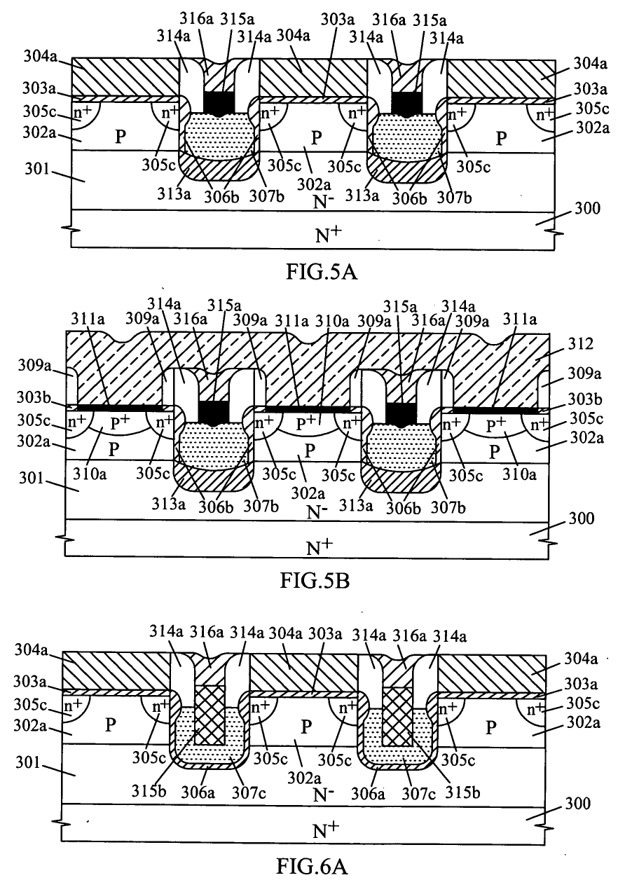

Referring now to FIG. 6A and FIG. 6B, there are shown simplified process steps after FIG. 4A and their schematic cross-sectional views of fabricating a fifth-type self-aligned trench-type DMOS transistor structure of the present invention.

FIG. 6A shows that the self-aligned heavily-doped polycrystalline-silicon gate layer 307b between the pair of capping sidewall dielectric spacers 314a is anisotropically etched to form a self-aligned trenched heavily-doped polycrystalline-silicon gate layer 307c; an etched-back conductive layer 315b is then formed to partially fill a gap between the pair of capping sidewall dielectric spacers 314a; and subsequently, a planarized capping oxide layer 316a is formed over the etched-back conductive layer 315b. The etched-back conductive layer 315b is preferably made of tungsten (W) or tungsten disilicide (WSi₂) as deposited by LPCVD and is formed by first depositing a conductive layer 315 (not shown) over a formed structure surface and then etching back to a predetermined thickness. Similarly, the planarized capping oxide layer 316a is formed by the process step as described in FIG. 4B.

Following the same process steps shown in FIG. 2H and FIG. 2G, FIG. 6B can be easily obtained. From FIG. 6B, it is clearly seen that FIG. 6B offers the etched-back conductive layer 315b being formed over the self-aligned trenched heavily-doped polycrystalline-silicon gate layer 307c to further reduce the gate-interconnection parasitic resistance, as compared to FIG. 4B.

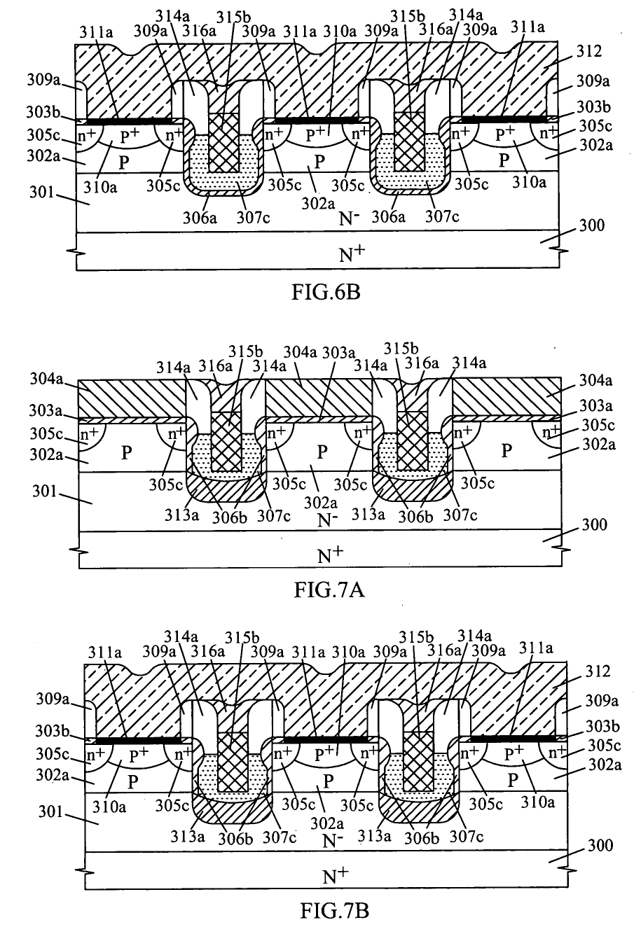

Referring now to FIG. 7A and FIG. 7B, there are shown simplified process steps after FIG. 3A and their schematic cross-sectional views of fabricating a sixth-type self-aligned trench-type DMOS transistor structure of the present invention.

FIG. 7A shows that a gate dielectric layer 306b is formed over each sidewall of trenched silicon surface; a self-aligned heavily-doped polycrystalline-silicon gate layer 307b is then formed over the gate dielectric layer 306b and on the thicker isolation dielectric layer 313a; a pair of capping sidewall dielectric spacers 314a are formed over sidewalls of the patterned masking dielectric layers 304a and on side surface portions of the self-aligned heavily-doped polycrystalline-silicon gate layer 307b; subsequently, the self-aligned heavily-doped polycrystalline-silicon gate layer 307b between the pair of capping sidewall dielectric spacers 314a is anisotropically etched to form a self-aligned trenched heavily-doped polycrystalline-silicon gate layer 307c; and thereafter, an etched-back conductive layer 315b is formed to partially fill a gap between the pair of capping sidewall dielectric layers 314a; and a planarized capping oxide layer 316a is formed on the etched-back conductive layer 315b. The etched-back conductive layer 315b is formed by the process steps as described in FIG. 6A and the planarized capping oxide layer 316a is also formed by the process steps as described in FIG. 6A.

Following the same process steps described in FIG. 2H and FIG. 2G, FIG. 7B can be easily obtained. From FIG. 7B, it is clearly seen that the etched-back conductive layer 315b together with the self-aligned trenched heavily-doped polycrystalline-silicon gate layer 307c may further reduce the gate-interconnection parasitic resistance as compared to FIG. 5B.

According to the above descriptions, the advantages and features of the present invention can be summarized below:
(a) The self-aligned trench-type DMOS transistor structure of the present invention is fabricated in a self-aligned manner and with less masking photoresist steps.
(b) The self-aligned trench-type DMOS transistor structure of the present invention offers a self-aligned heavily-doped n⁺ source diffusion ring and a self-aligned heavily-doped p⁺ contact diffusion region to reduce source contact resistance of a scaled trench-type DMOS transistor cell.
(c) The self-aligned trench-type DMOS transistor structure of the present invention offers a thicker isolation dielectric layer on a bottom trenched semiconductor surface to reduce gate to drain capacitance and to simultaneously increase gate and drain breakdown voltage.
(d) The self-aligned trench-type DMOS transistor structure of the present invention offers a self-aligned heavily-doped polycrystalline-silicon gate layer capped with a self-aligned refractory metal or refractory metal silicide layer to reduce gate-interconnection parasitic resistance.
(e) The self-aligned trench-type DMOS transistor structure of the present invention offers a self-aligned trenched heavily-doped polycrystalline-silicon gate layer being filled with a self-aligned refractory metal or refractory metal silicide layer to further reduce gate-interconnection parasitic resistance.
(f) The self-aligned trench-type DMOS transistor structure of the present invention offers a pair of capping sidewall dielectric spacers to reduce leakage current paths and overlapping capacitance between the self-aligned heavily-doped n⁺ source diffusion ring and the self-aligned heavily-doped polycrystalline-silicon gate layer or the self-aligned trenched heavily-doped polycrystalline-silicon gate layer.

The self-aligned trench-type n-channel DMOS transistor structure as described can be easily extended to fabricate self-aligned trench-type p-channel DMOS transistor structure by changing doping type in semiconductor regions. Moreover, the self-aligned trench-type DMOS transistor structure as described can be extended to fabricate insulated-gate bipolar transistors (IGBT) and MOS-controlled thyristor (MCT).

While the present invention has been particularly shown and described with reference to the present examples and embodiments as considered as illustrative and not restrictive. Moreover, the present invention is not to be limited to the details given herein, it will be understood by those skilled in the art that various changes in forms and details may be made without departure from the true spirit and scope of the present invention.

What is claimed is:

1. A self-aligned trench-type DMOS transistor structure, comprising:
a semiconductor substrate of a first conductivity type, wherein the semiconductor substrate comprises a lightly-doped epitaxial semiconductor layer being formed on a heavily-doped semiconductor substrate;
a self-aligned source region being formed on the lightly-doped epitaxial semiconductor layer surrounded by a trench gate region, wherein the self-aligned source region comprises a moderately-doped base diffusion region of a second conductivity type being formed in the lightly-doped epitaxial semiconductor layer, a heavily-doped source diffusion ring of the first conductivity type being formed in a side surface portion of the moderately-doped base diffusion region, a heavily-doped contact diffusion region of the second conductivity type being formed in a surface portion of the moderately doped base diffusion region surrounded by the heavily-doped source diffusion ring through a self-aligned implantation window, and a self-aligned source contact window being formed on the heavily-doped contact diffusion region surrounded by the heavily-doped source diffusion ring and the heavily-doped source diffusion ring surrounded by a sidewall dielectric spacer;
the trench gate region being formed in the lightly-doped epitaxial semiconductor layer through a patterned window, wherein the trench gate region comprises a shallow trench being formed to divide a heavily-doped diffusion region of the first conductivity type into the heavily-doped source diffusion ring and a moderately-doped diffusion region of the second conductivity type into a moderately-doped base diffusion region, a gate dielectric layer being formed over a trenched semiconductor surface, a self-aligned highly conductive gate layer being formed over the gate dielectric layer, and a capping dielectric layer being formed on the self-aligned highly conductive gate layer; and
a source metal layer being at least formed over the self-aligned source contact window in the self-aligned source region.

2. The self-aligned trench-type DMOS transistor structure according to claim 1, wherein the sidewall dielectric spacer being formed over a sidewall of the capping dielectric layer in the trench gate region and on a side surface portion of a buffer oxide layer in the self-aligned source region is used to form the self-aligned implantation window.

3. The self-aligned trench-type DMOS transistor structure according to claim 1, wherein the patterned window is formed by removing a masking dielectric layer on a buffer oxide layer in the trench gate region using a masking photoresist step.

4. The self-aligned trench-type DMOS transistor structure according to claim 1, wherein the moderately-doped diffusion region for forming the moderately-doped base diffusion region is formed by implanting a moderate dose of doping impurities into the lightly-doped epitaxial semiconductor layer.

5. The self-aligned trench-type DMOS transistor structure according to claim 1, wherein the heavily-doped diffusion region for forming the heavily-doped source diffusion ring is formed by implanting a high dose of doping impurities into a surface portion of the moderately-doped diffusion region through the patterned window.

6. The self-aligned trench-type DMOS transistor structure according to claim 1, wherein a thicker isolation dielectric layer is formed on a bottom trenched semiconductor surface in the shallow trench and the self-aligned highly conductive gate layer is formed over the gate dielectric layer and on the thicker isolation dielectric layer.

7. The self-aligned trench-type DMOS transistor structure according to claim 1, wherein the self-aligned highly conductive gate layer comprises a self-aligned heavily-doped polycrystalline-silicon gate layer with a thermal oxide layer being formed on the self-aligned heavily-doped polycrystalline-silicon gate layer to act as the capping dielectric layer.

8. The self-aligned trench-type DMOS transistor structure according to claim 1, wherein the self-aligned highly conductive gate layer comprises a self-aligned heavily-doped polycrystalline-silicon gate layer and a self-aligned refractory metal-silicide or refractory metal layer being formed on the self-aligned heavily-doped polycrystalline-silicon gate layer between a pair of capping sidewall dielectric spacers and the capping dielectric layer comprises the pair of capping sidewall dielectric spacers and a planarized capping oxide layer being formed between the pair of capping sidewall dielectric spacers.

9. The self-aligned trench-type DMOS transistor structure according to claim 1, wherein the self-aligned highly conductive gate layer comprises a self-aligned trenched heavily-doped polycrystalline-silicon gate layer and an etched-back self-aligned refractory metal silicide or refractory metal layer being formed over the self-aligned trenched heavily-doped polycrystalline-silicon gate layer between a pair of capping sidewall dielectric spacers and the capping dielectric layer comprises the pair of capping sidewall dielectric spacers and a planarized capping oxide layer being formed between the pair of capping sidewall dielectric spacers.

10. The self-aligned trench-type DMOS transistor structure according to claim 1, wherein the source metal layer comprises a self-aligned metal silicide layer being formed over the self-aligned source contact window and a metal layer over a barrier metal layer being at least formed over the self-aligned metal silicide layer.

11. A self-aligned trench-type DMOS transistor structure, comprising:
a single crystalline-silicon substrate of a first conductivity type, wherein the single crystalline-silicon substrate comprises a lightly-doped epitaxial silicon layer being formed on a heavily-doped silicon substrate;
a self-aligned source region being formed on the lightly-doped epitaxial silicon layer surrounded by a trench gate region, wherein the self-aligned source region comprises a moderately-doped base diffusion region of a second conductivity type being formed in the lightly-doped epitaxial silicon layer, a heavily-doped source diffusion ring of the first conductivity type being formed in a side surface portion of the moderately-doped base diffusion ring, a heavily-doped contact diffusion region of the second conductivity type being formed in a surface portion of the moderately-doped base diffusion region surrounded by the heavily-doped source diffusion ring through a self-aligned implantation window, and a self-aligned source contact window being formed on the heavily-doped contact diffusion region surrounded by the heavily-doped source diffusion ring and the heavily-doped source diffusion ring surrounded by a sidewall dielectric spacer being formed over a sidewall of the trench gate region and on a side surface portion of a buffer oxide layer;
the trench gate region being defined by a masking photoresist step to form a patterned window for sequentially forming a moderately-doped diffusion region of the second conductivity type in the lightly-doped epitaxial silicon layer and a heavily-doped diffusion region of the first conductivity type in a surface portion of the moderately-doped diffusion region, wherein the trench gate region further comprises a shallow trench being used to divide the heavily-doped diffusion region into the heavily-doped source diffusion region and the moderately-doped diffusion region into the moderately-doped base diffusion region, a gate dielectric layer being formed over a trenched silicon surface of the shallow trench, a self-aligned highly conductive gate layer being formed over the gate dielectric layer, and a capping dielectric layer being formed on the self-aligned highly conductive gate layer; and
a source metal layer being at least formed over the self-aligned source contact window in the self-aligned source region, wherein the source metal layer comprises a self-aligned metal silicide layer being formed over the self-aligned source contact window and a metal layer over a barrier metal layer being at least formed over the self-aligned metal-silicide layer.

12. The self-aligned trench-type DMOS transistor structure according to claim 11, wherein the patterned window is formed by removing a masking dielectric layer on the buffer oxide layer in the trench gate region and is also acted as an implantation window for forming the heavily-doped diffusion region.

13. The self-aligned trench-type DMOS transistor structure according to claim 11, wherein the self-aligned highly conductive gate layer comprises a self-aligned heavily-doped polycrystalline-silicon gate layer or a self-aligned heavily-doped polycrystalline-silicon gate layer being capped with a self-aligned refractory metal silicide or refractory metal layer formed between a pair of capping sidewall dielectric spacers.

14. The self-aligned trench-type DMOS transistor structure according to claim 11, wherein the self-aligned highly conductive gate layer comprises a self-aligned trenched heavily-doped polycrystalline-silicon gate layer and an etched-back self-aligned refractory metal silicide or refractory metal layer being formed over the self-aligned trenched heavily-doped polycrystalline-silicon gate layer between a pair of capping sidewall dielectric spacers.

15. A self-aligned trench-type DMOS transistor structure, comprising:
a single crystalline-silicon substrate of a first conductivity type, wherein the single crystalline-silicon substrate comprises a lightly-doped epitaxial silicon layer being formed on a heavily-doped silicon substrate;
a self-aligned source region being formed on the lightly-doped epitaxial silicon layer surrounded by a trench gate region, wherein the self-aligned source region comprises a moderately-doped base diffusion region of a second conductivity type being formed in the lightly-doped epitaxial silicon layer, a heavily-doped source diffusion ring of the first conductivity type being formed in a side surface portion of the moderately-doped base diffusion region, a heavily-doped contact diffusion region of the second conductivity type being formed in a surface portion of the moderately-doped base diffusion region surrounded by the heavily-doped source diffusion ring through a self-aligned implantation window being surrounded by a sidewall dielectric spacer, and a self-aligned source contact window being formed on the heavily-doped contact diffusion region surrounded by the heavily-doped source diffusion ring and the heavily-doped source diffusion ring surrounded by the sidewall dielectric spacer;
the trench gate region being defined by a masking photoresist step to form a patterned window for sequentially forming a moderately-doped diffusion region of the second conductivity type in the lightly-doped epitaxial silicon layer and a heavily-doped diffusion region of the first conductivity type in a surface portion of the moderately-doped diffusion region, wherein the trench gate region further comprises a shallow trench being used to divide the heavily-doped diffusion region into the heavily-doped source diffusion ring and the moderately-doped diffusion region into the moderately-doped base diffusion region, a thicker isolation dielectric layer being formed on a bottom trenched silicon surface of the shallow trench and a gate dielectric layer being formed over each sidewall of the shallow trench, a self-aligned highly conductive gate layer being formed over the gate dielectric layer and on the thicker dielectric layer and a capping dielectric layer being formed on the self-aligned highly conductive gate layer; and
a source metal layer being at least formed over the self-aligned source contact window in the self-aligned source region, wherein the source metal layer comprises a self-aligned refractory metal silicide layer being formed over the self-aligned source contact window and a metal layer over a barrier-metal layer being at least formed over the self-aligned refractory metal-silicide layer.

16. The self-aligned trench-type DMOS transistor structure according to claim 15, wherein the sidewall dielectric spacer being made of silicon nitride is formed over a sidewall of the capping dielectric layer in the trench gate region and on a side surface portion of a buffer oxide layer in the self-aligned source region to form the self-aligned implantation window.

17. The self-aligned trench-type DMOS transistor structure according to claim 15, wherein the self-aligned highly conductive gate layer comprises a self-aligned heavily-doped polycrystalline-silicon gate layer capped with a thermal oxide layer to act as the capping dielectric layer.

18. The self-aligned trench-type DMOS transistor structure according to claim 15, wherein the self-aligned highly conductive gate layer comprises a self-aligned heavily-doped polycrystalline-silicon gate layer capped with a self-aligned refractory metal silicide or refractory metal layer being formed between a pair of capping dielectric spacers.

19. The self-aligned trench-type DMOS transistor structure according to claim 15, wherein the self-aligned highly conductive gate layer comprises a self-aligned trenched heavily-doped polycrystalline-silicon gate layer and an etched-back self-aligned refractory metal silicide or refractory metal layer being formed over the self-aligned trenched heavily-doped polycrystalline-silicon gate layer between a pair of capping sidewall dielectric spacers.

20. The self-aligned trench-type DMOS transistor structure according to claim 15, wherein the thicker isolation dielectric layer being made of silicon dioxide is formed by first depositing a silicon dioxide layer to fill the shallow trench and then etching back the deposited silicon dioxide layer to a depth equal to or lower than a junction depth of the moderately-doped base diffusion region.
